(19) United States
(12) Patent Application Publication
(10) Pub. No.: US 2013/0106242 A1
(43) Pub. Date: May 2, 2013

(54) PIEZOELECTRIC FILM ELEMENT AND PIEZOELECTRIC FILM DEVICE

(71) Applicants: Kenji Shibata, Tsukuba-shi (JP); Kazufumi Suenaga, Tsuchiura-shi (JP); Kazutoshi Watanabe, Tsuchiura-shi (JP); Akira Nomoto, Kasumigaura-shi (JP); Fumimasa Horikiri, Nagareyama-shi (JP)

(72) Inventors: Kenji Shibata, Tsukuba-shi (JP); Kazufumi Suenaga, Tsuchiura-shi (JP); Kazutoshi Watanabe, Tsuchiura-shi (JP); Akira Nomoto, Kasumigaura-shi (JP); Fumimasa Horikiri, Nagareyama-shi (JP)

(73) Assignee: HITACHI CABLE, LTD., Tokyo (JP)

(21) Appl. No.: 13/808,718

(22) PCT Filed: Mar. 30, 2011
(86) PCT No.: PCT/JP2011/057950

§ 371 Date: Jan. 7, 2013

(30) Foreign Application Priority Data
Jul. 7, 2010 (JP) 2010-155165

(51) Int. Cl. H01L 41/187; H01L 41/18

(52) U.S. Cl. CPC H01L 41/1873; H01L 41/18
USPC 310/311; 252/62.9 R; 428/702; 428/471; 428/450

(57) ABSTRACT

To provide a piezoelectric film element, including: a substrate; and a piezoelectric film having an alkali niobium oxide-based perovskite structure represented by a composition formula (K₁₋ₓNaₓ)_{y}NbO₃ (0<x<1) provided on the substrate, wherein the alkali niobium oxide-based composition falls within a range of 0.40≦x≦0.70 and 0.77≦y≦0.90, and further a ratio of an out-of-plane lattice constant (c) to an in-plane lattice constant (a) of the (K₁₋ₓNaₓ)_{y}NbO₃ film is set in a range of 0.985≦c/a≦1.008.

### TECHNICAL FIELD

The present invention relates to a piezoelectric film element and a piezoelectric film device using an alkali niobium oxide-based piezoelectric film.

### DESCRIPTION OF RELATED ART

A piezoelectric material is processed into various piezoelectric elements for various purposes of use, and is widely utilized as functional electronic components such as an actuator for generating deformation under application of voltage and a sensor for generating voltage from the deformation of an element reversely. A dielectric material made of lead-based materials having excellent piezoelectric properties, and particularly Pb (Zr₁₋ₓTiₓ)O₃-based perovskite ferroelectrics called PZT, are widely used as a piezoelectric material utilized for the purpose of use of the actuator and sensor. Usually, the piezoelectric material such as PZT is formed by sintering an oxide composed of individual elements. At present, miniaturization and higher performance are strongly requested for the piezoelectric element, with a progress of the miniaturization and higher performance of each kind of electronic components.

However, there is a problem in the piezoelectric material fabricated by a producing method focusing on a sintering method being a conventional preparing method, as follows. As the piezoelectric material is made thinner and particularly as its thickness becomes close to about 10 μm, a size of the piezoelectric material becomes close to a size of crystal grains constituting the material, thus posing a problem that variation and deterioration of the characteristic are great. In order to avoid the aforementioned problem, a method for forming a piezoelectric material applying a thin film technique instead of the sintering method has been studied in recent years. In recent years, a PZT thin film formed on a silicon substrate by sputtering, is put to practical use as the piezoelectric film for an actuator for a high-speed and high-definition inkjet printer head.

Meanwhile, a piezoelectric sintered compact and the piezoelectric film made of PZT contains lead by about 60 to 70 wt %, and therefore are not preferable from an aspect of an ecological standpoint and pollution control. Therefore, it is desired to develop a piezoelectric material not containing lead in consideration of an environment. At present, various lead-free piezoelectric materials are studied, and above all, potassium sodium niobate represented by a composition formula: (K₁₋ₓNaₓ)NbO₃ (0<x<1) can be given as an example (for example, see patent document 1 and patent document 2). Such potassium sodium niobate includes a material having a perovskite structure, and is expected as a strong candidate of the lead-free piezoelectric material.

The KNN film is attempted to be formed on a silicon substrate by a film formation method such as a sputtering method, a sol gel method, and an aerosol deposition method, and according to patent document 3, piezoelectric constant d₃₁=−100 pm/V or more which is a practical level can be realized by setting a ratio of an out-of-plane lattice constant (c) to an in-plane lattice constant (a) of the KNN piezoelectric film in a range of 0.980≦c/a≦1.010.

### PRIOR ART DOCUMENTS

### Patent Documents

Patent document 1:

### Japanese Patent Laid Open Publication No. 2007-184513

Patent document 2:

### Japanese Patent Laid Open Publication No. 2008-159807

Patent document 3:

### Japanese Patent Laid Open Publication No. 2009-295786

### SUMMARY OF THE INVENTION

### Problem to be Solved by the Invention

However, when an element is fabricated by the KNN film, there is a problem that piezoelectric properties are deteriorated by a long-term use. For example, when a piezoelectric film is formed in an actuator of an ink jet printer head, it is requested that 95% or more piezoelectric properties or preferably 100% piezoelectric properties are realized after 100 billion times drive, with an initial characteristic as a reference. However, such a request has not been satisfied yet, and an application to a product is difficult at present.

An object of the present invention is to provide a piezoelectric film element and a piezoelectric film device using an alkali niobium oxide-based piezoelectric film having piezoelectric properties which can be substituted with the present PZT film.

### Means for Solving the Problem

According to an aspect of the present invention, there is provided a piezoelectric film element, including:

a substrate; and

a piezoelectric film having an alkali niobium oxide-based perovskite structure represented by a composition formula (K₁₋ₓNaₓ)_{y}NbO₃ (0<x<1) provided on the substrate,

wherein the alkali niobium oxide-based composition falls within a range of 0.40≦x≦0.70 and 0.77≦y≦0.90, and further a ratio of an out-of-plane lattice constant (c) to an in-plane lattice constant (a) of the KNN piezoelectric film is set in a range of 0.985≦c/a≦1.008.

In this case, preferably when there are multiple layers of the piezoelectric film, a layer with a thickest thickness out of the multiple layers satisfies the range of the composition and the c/a ratio.

Further preferably, the piezoelectric film has a pseudo-cubic structure and is preferentially oriented in (001) plane direction.

Further preferably, a base layer is provided between the substrate and the piezoelectric film.

Further preferably, the base layer is a Pt film or an alloy film mainly composed of Pt, or an electrode layer with a lamination structure including a lower electrode mainly composed of Pt.

Further preferably, an upper electrode formed on the piezoelectric film.

Further preferably, the substrate is a Si substrate, a surface oxide film-attached Si substrate, or an SOI substrate.

Further, according to other aspect of the present invention, there is provided a piezoelectric film device, including:

the piezoelectric film element; and

a function generator or a voltage detector connected between the lower electrode and the upper electrode.

### Advantage of the Invention

According to the present invention, there is provided a piezoelectric film element and a piezoelectric film device using an alkali niobium oxide-based piezoelectric film having piezoelectric properties which can be substituted with the present PZT film.

### BRIEF DESCRIPTION OF THE DRAWINGS

FIG. 1 is a schematic view showing a structure of a piezoelectric film element according to an embodiment of the present invention.

FIG. 2 is a schematic view showing the structure of the piezoelectric film element according to other embodiment of the present invention.

FIG. 3 is a schematic view showing the structure of the piezoelectric film device fabricated using the piezoelectric film element according to an embodiment of the present invention.

FIG. 4 is an explanatory view regarding an out-of-plane lattice constant (c) and an in-plane lattice constant (a) of a KNN film on a substrate according to an embodiment of the present invention.

FIG. 5 is an explanatory view of an X-ray diffraction measurement by a 2θ/θ method according to an embodiment of the present invention.

FIG. 6 is a graph showing a measurement result of an X-ray diffraction pattern by the 2θ/θ method performed to the KNN film according to an embodiment of the present invention.

FIG. 7 is an explanatory view of an X-ray diffraction measurement by an In-Plane method according to an embodiment of the present invention.

FIG. 8 is a graph showing the measurement result of an X-ray diffraction pattern by the In-Plane method performed to the KNN film according to an embodiment of the present invention.

FIG. 9 is a schematic block diagram describing a structure of an actuator fabricated using the piezoelectric film element and a method for evaluating piezoelectric properties according to an embodiment of the present invention.

FIG. 10 is a graph showing a relation between d₃₁ after drive of one billion times/initial d₃₁×100(%), and a c/a ratio of the KNN film according to an example of the present invention and a comparative example.

FIG. 11 is a graph showing a relation between d₃₁ after drive of one billion times/initial d_{31×100}(%), and a (K+Na)/Nb ratio of the KNN film according to an example of the present invention and a comparative example.

FIG. 12 is a schematic view showing a structure of a filter device according to an embodiment of the present invention.

### DETAILED DESCRIPTION OF THE INVENTION

[Outline of the Invention]

Inventors of the present invention pay attention to a ratio of an out-of-plane lattice constant (c) to an in-plane lattice constant (a) (c/a ratio) and simultaneously x=Na/(K+Na) ratio and y=(K+Na)/Nb ratio of a KNN film, to examine a relation with piezoelectric properties after one billion times drive. As a result, it is found that when the c/a ratio is in a range of 0.985≦c/a≦1.008, and composition x and composition y are in a range of 0.40≦x≦0.70 and 0.77≦y≦0.90, initial piezoelectric constant d₃₁ is −100 pm/V or more and a ratio of the piezoelectric constant after one billion times drive with respect to an initial piezoelectric constant is 95% or more (see example 1 to example 22).

The piezoelectric film element according to an embodiment of the present invention will be described hereafter.

[Structure of the Piezoelectric Film Element]

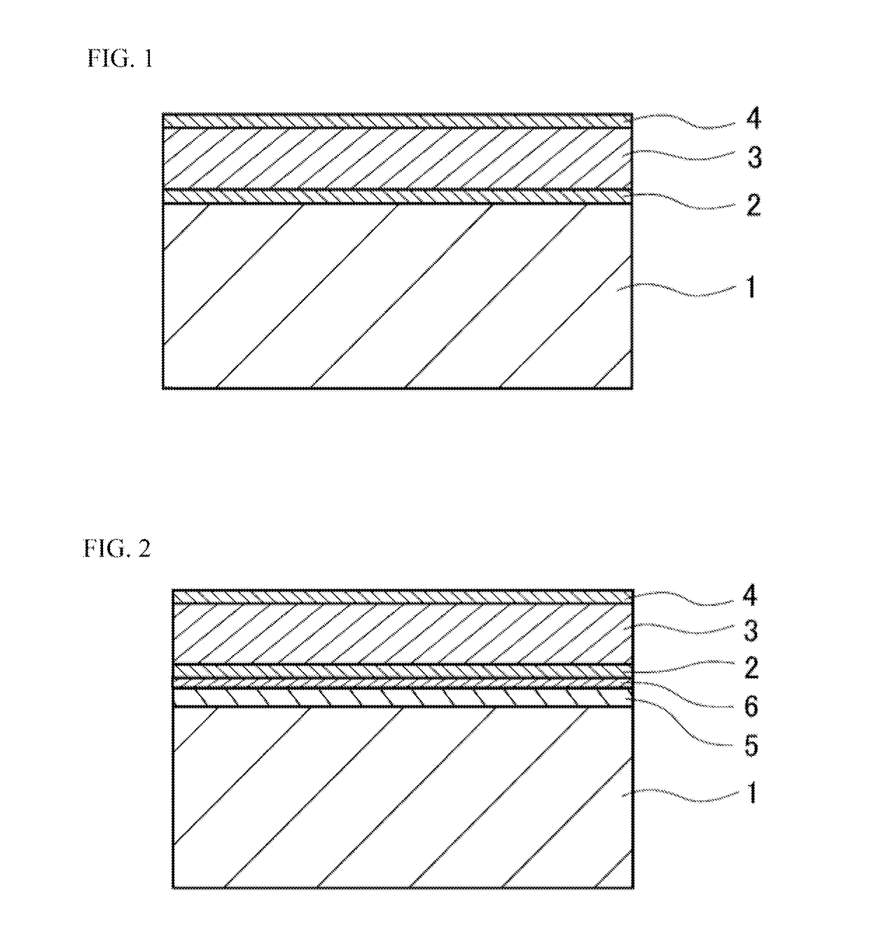

FIG. 1 is a cross-sectional view showing a schematic structure of the piezoelectric film element according to an embodiment of the present invention. As shown in FIG. 1, a lower electrode 2 and a piezoelectric film 3 and an upper electrode 4 are sequentially formed on a substrate 1.

A Si (silicon) substrate, an oxide film-attached Si substrate, or a SOI (Silicon On Insulator) substrate is preferably used as the substrate 1. For example, (100) Si substrate with a Si substrate plane oriented in (100) plane direction is used as the Si substrate. However, of course the Si substrate having a plane direction different from that of the (100) plane may also be used. Further, as the substrate, a quartz glass substrate, a GaAs substrate, a sapphire substrate, a metal substrate such as stainless, a MgO substrate, and a SrTiO₃ substrate, etc., may also be used.

Preferably, the lower electrode 2 is made of Pt (platinum), and a Pt layer is oriented in (111) plane direction. For example, the Pt layer formed on the Si substrate is easily oriented in (111) plane direction, due to its self-orientation performance. The lower electrode 2 may be an alloy film mainly composed of Pt, or may be a metal film made of Au (gold) , Ru(ruthenium), Ir(iridium), or may be an electrode film using a metal oxide such as SrRuO₃, LaNiO₃, or may be an electrode layer having a lamination structure including the lower electrode mainly compose of Pt. The lower electrode 2 is formed using a sputtering method and a vapor deposition method, etc. Note that in order to obtain a high adhesion between the substrate 1 and the lower electrode 2, an adhesive layer may be provided between the substrate 1 and the base layer 2.

The piezoelectric film 3 has an alkali nioubium oxide-based perovskite structure represented by a composition formula (K₁₋ₓNaₓ)_{y}NbO₃ (abbreviated as “KNN” hereafter), wherein composition x=Na/(K+Na)ratio, and composition y=(K+Na)/Nb ratio is in a range of 0.40≦x≦0.70 and 0.77≦y≦0.90, and the ratio of the out-of-plane lattice constant (c) to the in-plane lattice constant (a) of the KNN piezoelectric film is set in a range of 0.985≦c/a≦1.008. The piezoelectric film 3 is formed by the sputtering method, CVD (Chemical Vapor Deposition) method, and sol gel method, etc.

Similarly to the lower electrode 2, the upper electrode 4 is formed by the sputtering method, the vapor deposition method, a plating method, and a metal paste method, using materials such as Pt, Au, Al (aluminum). The electrode 4 does not have a great influence on a crystal structure of the piezoelectric film like the lower electrode 2, and therefore the material and the crystal structure of the electrode 4 are not particularly limited.

[Method for Fabricating the KNN Film]

A method for fabricating the KNN film in a range of 0.40≦x≦0.70 and 0.77≦y≦0.90 includes a method of forming a film by the sputtering method using a target in which K and Na are smaller than a stoichiometry composition (y=(K+Na)/Nb=1), namely y is smaller than 1.

Further, a method for fabricating the KNN film with the c/a ratio in a range of 0.985≦c/a≦1.008 includes a method of controlling a H₂O partial pressure that exists in Ar/O₂ gas mixed atmosphere during film formation by sputtering. Although Ar/O₂ mixed gas is used as an atmosphere gas during film formation by sputtering, moisture that exists inside of a chamber is mixed into an atmosphere gas, although its ratio is extremely small. The c/a ratio of the KNN film significantly depends on an orientation state of the KNN film in (001) plane direction, and the c/a ratio is likely to be large in a case of a high (001) orientation, and the c/a ratio is likely to be small in a case of a low (001) orientation. The (001) orientation state of the KNN film is greatly depends on a H₂O partial pressure contained in the atmosphere gas during sputtering film formation, and when the H₂O partial pressure is high, the orientation state becomes a low (001) orientation, and when the H₂O partial pressure is low, the orientation state becomes a high (001) orientation. Namely, the c/a ratio of the KNN film can be controlled by strictly controlling the H₂O partial pressure in the atmosphere gas.

The aforementioned calculation of the out-of-plane lattice constant (c) to the in-plane lattice constant (a), and an evaluation of the piezoelectric properties will be described hereafter.

### (Calculation of the Out-of-Plane Lattice Constant (c) to the In-Plane Lattice Constant (a))

As shown in FIG. 4, the out-of-plane lattice constant (c) means a lattice constant of the KNN film in a direction (out-of-plane direction) vertical to a substrate (Si substrate) plane and a KNN piezoelectric film plane, and the in-plane lattice constant (a) means a lattice constant of the KNN film in a direction (in-plane-direction) parallel to the substrate (Si substrate) plane and the KNN piezoelectric film plane. Values of the out-of-plane lattice constant (c) and the in-plane lattice constant (a) are numerical values calculated from a diffraction peak angle obtained by an X-ray diffraction pattern.

The calculation of the out-of-plane lattice constant (c) and the in-plane lattice constant (a) will be descried hereafter in detail.

The KNN piezoelectric film of this embodiment formed on the Pt lower electrode has a polycrystalline columnar structure and is self-oriented in (111) plane direction. Therefore, the KNN film succeeds to have a crystal orientation of the Pt lower electrode, to become a polycrystalline film having the columnar structure being a perovskite structure. Namely, although the KNN film is preferentially oriented in (001) plane direction, there is no preferential orientation of the in-plane-direction in an arbitrary direction, and the orientation state is random.

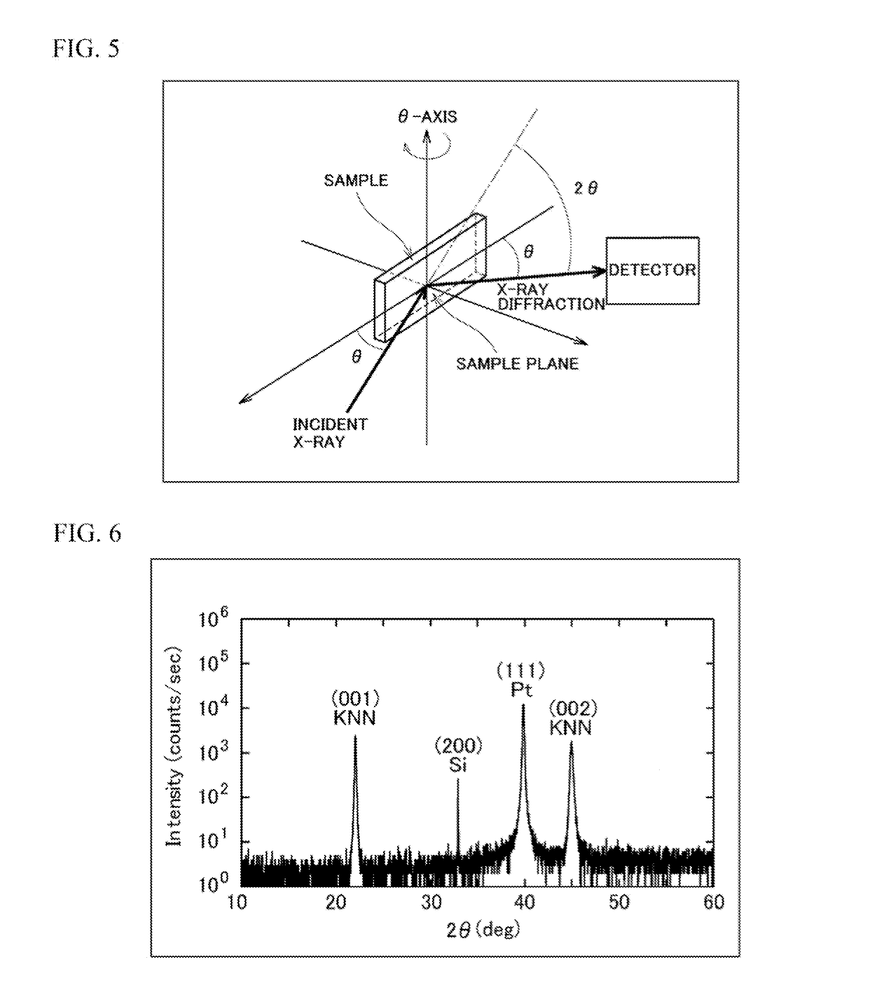

The preferential orientation of the KNN film in the out-of-plane (001) plane direction in the perovskite structure, can be judged as follows: namely, it can be judged when a diffraction peak of (001) plane and (002) plane is higher than other peak caused by the KNN film in the X-ray diffraction pattern (FIG. 6) which is obtained by the X-ray diffraction measurement (FIG. 5) performed to the KNN film by the 2θ/θ method. According to this embodiment, based on JCPDS -International Center for Diffraction Data regarding KNbO₃ and NaNbO₃, the diffraction peak in a range of 22.011°≦2θ≦22.890° is considered to be (001) plane diffraction peak, and the diffraction peak in a range of 44.880°≦2θ≦46.789° is considered to be (002) plane diffraction peak.

The out-of-plane lattice constant (c) of this embodiment was calculated by a method as follows. First, the X-ray diffraction pattern was measured by the X-ray diffraction measurement (2θ/θ method) shown in FIG. 5 using a normal Cu Kα1 ray. In this X-ray diffraction measurement, usually, a sample and a detector are scanned around the θ-axis shown in FIG. 5, to thereby measure diffraction from a lattice plane parallel to a sample plane.

The value of θ obtained from a diffraction peak angle 2θ of the KNN (002) plane in the obtained X-ray diffraction pattern (FIG. 6), and a wavelength λ=0.154056 of the Cu Kα1 ray, were substituted into a Bragg's equation 2d sin θ=nλ, to thereby calculate a plane interval c(002) (=c/2) of the KNN (002) plane. A value two times higher than the plane interval c(002) was set as the out-of-plane lattice constant (c).

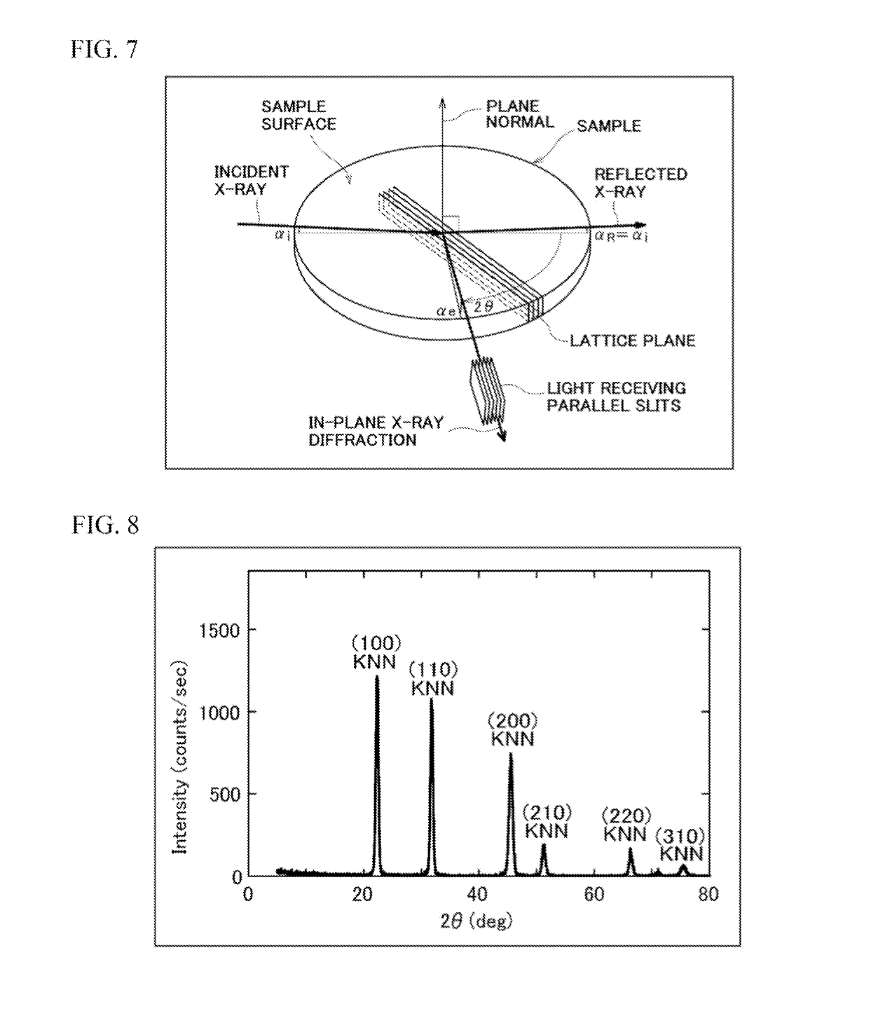

The in-plane lattice constant (a) of this embodiment was calculated by the following method. The X-ray diffraction pattern was measured by the In-plane X-ray diffraction measurement shown in FIG. 7 using the Cu Kα1 ray. In this X-ray diffraction measurement, usually, observation points of the sample plane by the detector including light receiving parallel slits shown in FIG. 7, are set so that the diffraction is measured from the lattice plane vertical to the sample plane.

The value of θ obtained from the diffraction peak angle 2θ of the KNN (200) plane in the obtained X-ray diffraction pattern (FIG. 8), and a wavelength λ=0.154056 nm of the Cu Kα1 raye, were substituted into the Bragg's equation 2d sin θ=nλ, to thereby calculate a plane interval a(200) (=a/2) of the KNN (200) plane. A value two times higher than the plane interval a (200) was set as the in-plane lattice constant (a). In the X-ray diffraction pattern by the In-plane X-ray diffraction method as well, the diffraction peak in a range of 44.880°≦ 2θ≦46.789° is considered to be (002) plane diffraction peak based on JCPDS-International Center for Diffraction Data regarding KNbO₃ and NaNbO₃.

When the obtained KNN film is formed not in a state of a single domain where either c-domain or a-domain exists alone, but in a tetragonal system where the c-domain and the a-domain coexist, a KNN (002) diffraction peak is obtained in the vicinity of the KNN(002) plane diffraction peak in a case of the X-ray diffraction pattern based on the 2θ/θ method, and a KNN(200) plane diffraction peak is obtained in the vicinity of the KNN(200) plane diffraction peak in a case of the In-plane X-ray diffraction pattern. In such a case, the out-of-plane lattice constant (c) and the in-plane lattice constant (a) are calculated using a peak angle of one of the neighboring two diffraction peaks having a greater peak intensity (namely in a dominant domain).

Further, in the measurement of the In-plane X-ray diffraction (minute incidence angle X-ray diffraction), only a region in the vicinity of the sample plane can be measured. Therefore, the In-plane measurement of this embodiment was performed in a state that the upper electrode was not placed on the KNN film. In a case of the sample with the upper electrode formed on the KNN film, the upper electrode is removed by dry etching, wet etching, and polishing, etc., to expose the plane of the KNN piezoelectric film, and thereafter the In-plane X-ray diffraction measurement may be executed. Regarding the dry etching, the dry etching by Ar plasma is used when removing the Pt upper electrode.

[Experiment of the Actuator and Evaluation of the Piezoelectric Properties]

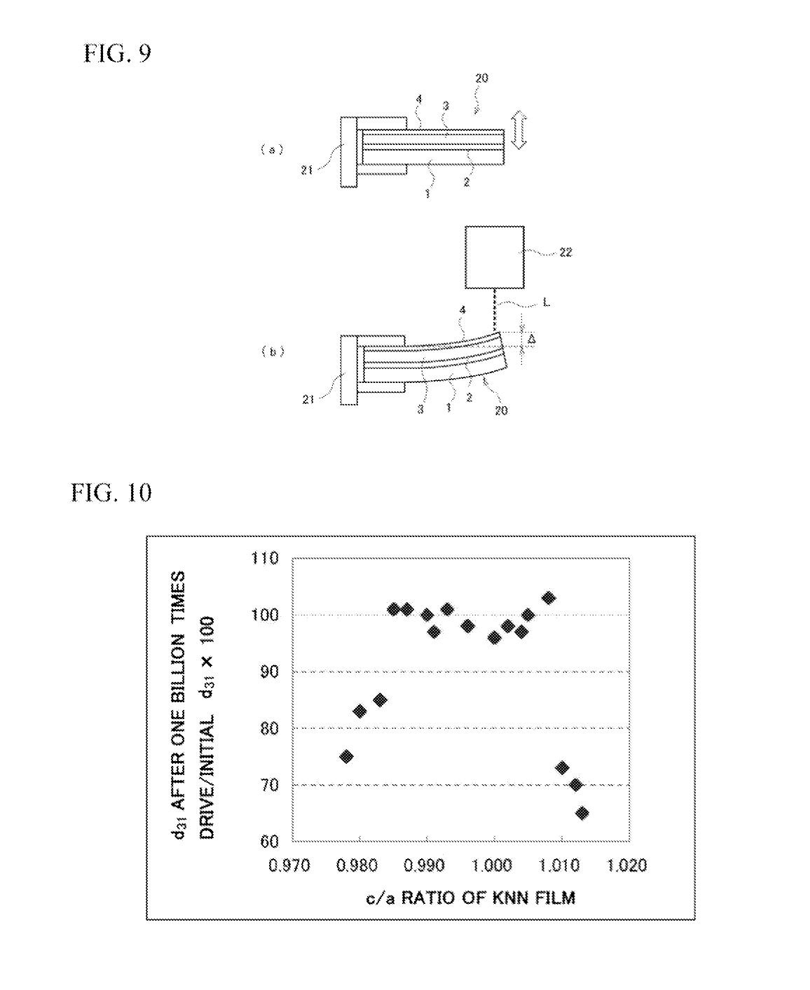

In order to evaluate the piezoelectric constant d₃₁ of the KNN piezoelectric film, a unimorph cantilever having a structure shown in FIG. 9(a) was experimented. First, the Pt upper electrode was formed on the KNN piezoelectric film of this embodiment by a RF magnetron sputtering method, which was then cut-out into rectangular beams, to thereby fabricate the piezoelectric film element having the KNN piezoelectric film. Next, a longitudinal end of the piezoelectric film element was fixed by a clamp, to thereby fabricate a simple unimorph cantilever. Voltage was applied to the KNN piezoelectric film between the upper electrode and the lower electrode of this cantilever to bend an entire body of the cantilever by expanding and contracting the KNN film so that a tip end of the cantilever reciprocates in a vertical direction (thickness direction of the KNN piezoelectric film). At this time, displacement amount Δ of the cantilever was measured by irradiating the tip end of the cantilever with laser beams from a laser Doppler displacement meter (FIG. 9(b)). The piezoelectric constant d₃₁ was calculated from the displacement amount Δ of the tip end of the cantilever, a length of the cantilever, a thickness and the Young modulus of the substrate and the KNN piezoelectric film, and an application voltage. The piezoelectric constant d₃₁ was calculated by a method described in document 1 described below.

Document 1: T. Mino, S. Kuwajima, T. Suzuki, I. Kanno, H. Kotera, and K. Wasa: Jpn. J. Appl. Phys. 46 (2007) 6960

### Effect of the Embodiment

According to this embodiment, the composition of (K₁₋ₓNaₓ₎_{y}NbO₃ is in a range of 0.40≦x 0.70 and 0.77≦y≦0.90, and the ratio of the out-of-plane lattice constant (c) to the in-plane lattice constant (a) of the KNN piezoelectric film is in a range of 0.985 c/a 1.008. Therefore, the piezoelectric film element and the piezoelectric film device using the alkali niobium oxide-based piezoelectric film having the piezoelectric properties which can be substituted with the present PZT film, can be provided. For example, when the piezoelectric film element of this embodiment is used in the actuator of an inkjet printer, 95% or more of the piezoelectric properties or 100% thereof in some cases after one billion times drive can be realized, with an initial property as a reference, and therefore application to a product is facilitated.

### Other Embodiment

### (An Oxide Film-Attached Substrate)

FIG. 2 shows a schematic cross-sectional structure of the piezoelectric film element according to other embodiment of the present invention. Similarly to the piezoelectric film element according to the aforementioned embodiment shown in FIG. 1, the piezoelectric film element of this embodiment has the lower electrode 2, the piezoelectric film 3, and the upper electrode 4 on the substrate 1. However, as shown in FIG. 2, the substrate 1 is the surface oxide film-attached substrate in which an oxide film 5 is formed on its surface, and an adhesive layer 6 is provided between the oxide film 5 and the base layer 2 to increase adhesion of the lower electrode 2.

The surface oxide film-attached substrate is for example a Si substrate to which an oxide film is attached, and in the surface oxide film-attached Si substrate, the oxide film 5 includes a SiO₂ film formed by thermal oxidation, and a SiO₂ film formed by the CVD method. As a substrate size, usually a circular shape of 4 inches is used in many cases. However, a circular shape or a rectangular shape of 6 inches or 8 inches may also be used. Further, the adhesive layer 6 is formed by the sputtering method and the vapor deposition method using Ti (titanium) and Ta (tantalum).

### (Single Layer/Multiple Layers)

Further, the piezoelectric film of the piezoelectric film element of the aforementioned embodiment is a single layer KNN film. However, the piezoelectric film 3 may also be formed of multiple (K₁₋ₓNaₓ)_{y}NbO₃ (0<x<1) layers including the KNN film in a range of 0.40≦x≦0.70 and 0.77≦y≦0.90.

Further, an element other than K (potassium), Na (sodium), Nb (niobium), O (oxygen), for example, Li (lithium), Ta (tantalum), Sb (antimony), Ca (calcium), Cu (copper), Ba (barium), Ti (titanium), etc., maybe added to the piezoelectric film of KNN by 5 several atom % or less. In this case as well, a similar effect can be obtained. Further, a thin film made of an alkali niobium oxide-based material other than KNN or a material having the perovskite structure (LaNiO₃, SrTiO₃, LaAlO₃, YAlO₃, BaSnO₃, BaMnO₃, etc.,) may also be included between the lower electrode 2 and the upper electrode 4.

### (Piezoelectric Film Device)

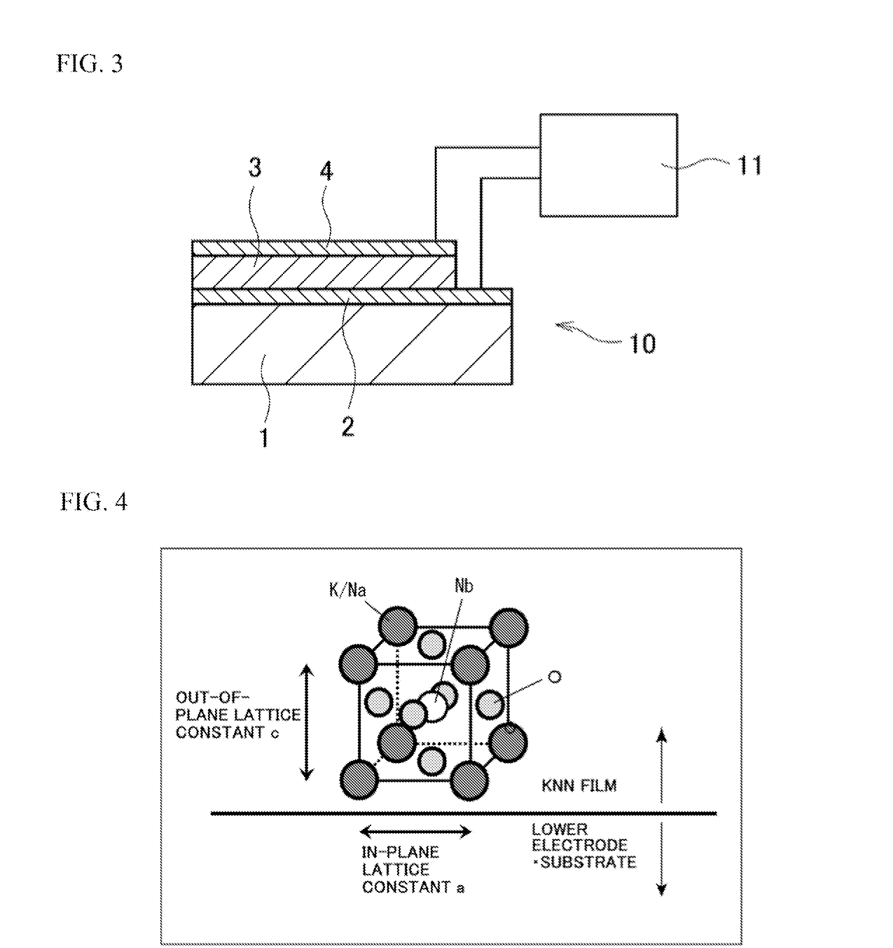

FIG. 3 shows a schematic block diagram of a piezoelectric film device according to other embodiment of the present invention.

As shown in FIG. 3, in the piezoelectric film device, at least the voltage detector or the function generator 11 is connected between the lower electrode 2 and the upper electrode 4 of the piezoelectric film element which is formed into a prescribed shape. By connecting the voltage detector 11 between the lower electrode 2 and the upper electrode 4, a sensor as the piezoelectric film element can be obtained. When the piezoelectric film element of the sensor is deformed by a change of some physical quantity, voltage is generated by such a deformation, and therefore each kind of physical quantity can be measured by detecting the voltage by the voltage detector 11. For example, a gyro sensor, an ultrasonic sensor, a pressure sensor, and a speed/acceleration sensor, etc., can be given as the sensor.

Further, the actuator being the piezoelectric film element, is obtained by connecting the function generator 11 between the lower electrode 2 and the upper electrode 4 of the piezoelectric film element 10. Each kind of members can be operated by applying voltage to the piezoelectric film element 10, and deforming the piezoelectric film element 10. The actuator can be used for an inkjet printer, a scanner, and an ultrasonic generator, etc., for example.

In the aforementioned embodiment, an embodiment of using the Pt film as an orientation control layer, is provided. However, LaNiO₃ can also be used, which is easily oriented in (001) plane, on the Pt film or instead of the Pt film. Further, the KNN film may be formed through NaNbO₃. Moreover, it is also acceptable that the piezoelectric film is formed on the substrate, and an electrode having a prescribed shape is formed on the piezoelectric film, and a filter device utilizing a surface acoustic wave is formed. FIG. 12 shows a structure of such a filter device. The filter device is configured by forming a LaNiO₃ layer 31, a NaNbO₃ layer 32, the KNN film 4, and an upper pattern electrode 51 on the Si substrate 1. Here, a base layer is formed by the LaNiO₃ layer 31 and the NaNbO₃ layer 32.

### EXAMPLES

Examples of the present invention will be described next, together with comparative examples.

The piezoelectric film element of an example and a comparative example has a cross-sectional structure similar to that of the second embodiment shown in FIG. 2, wherein the Ti adhesive layer, Pt lower electrode, KNN piezoelectric film, and Pt upper electrode are laminated on the Si substrate having a thermal oxide film.

### [Film Formation of the KNN Piezoelectric Film]

A film formation method of the KNN piezoelectric film according to the example and the comparative example will be described hereafter.

The thermal oxide film-attached Si substrate ((100) plane direction, thickness: 0.525 mm, shape: circular shape of 4 inches, thickness of the thermal oxide film: 200 nm) was used as the substrate. First, the Ti adhesive layer (film thickness: 10 nm) and the Pt lower electrode ((111) plane preferential orientation, film thickness: 200 nm) was formed on the substrate by a RF magnetron sputtering method. The Ti adhesive layer and the Pt lower electrode were formed under conditions of substrate temperature: 350° C., discharge power: 300 W, introduced gas: Ar, pressure of Ar atmosphere: 2.5 Pa, film formation time: 3 minutes for the Ti adhesive layer, and 10 minutes for the Pt lower electrode.

Subsequently, (K₁₋ₓNaₓ)_{y}NbO₃ piezoelectric film having the film thickness of 3 μm was formed on the Pt lower electrode by the RF magnetron sputtering method. The (K₁₋ₓNaₓ₎_{y}NbO₃ piezoelectric film was formed using (K₁₋ₓNaₓ)_{y}NbO₃ sintered compact as a target, wherein the (K+Na)/Nb ratio=0.82 to 1.08, Na/(K+Na) ratio=0.44 to 0.77, under conditions of substrate temperature (temperature of the substrate plane): 550° C., discharge power: 75 W, introduced gas Ar/O₂ mixed gas (Ar/O₂=99/1), pressure of atmosphere gas: 1.3 Pa. The (K₁₋ₓNaₓ)_{y}NbO₃ sintered compact target was fabricated by using K₂CO₃ powder, Na CO₃ powder, and Nb₂O₅ powder as raw materials, and mixing them using a ball mill for 24 hours, and temporarily sintering them for 10 hours at 850° C., and thereafter pulverizing them by the ball mill again, and molding them under a pressure of 200 MPa, and thereafter sintering them at 1080° C.

The (K+Na) /Nb ratio and the Na/(K+Na) ratio were controlled by adjusting a mixing ratio of the K₂CO₃ powder, the Na CO₃ powder, and the Nb₂O₅ powder. Atomic number % of K, Na, and Nb of the fabricated target were calculated by EDX (Energy Dispersive X-ray spectrometry) before using this target for sputtering film formation, to thereby calculate the (K+Na)/Nb ratio and the Na/(K+Na) ratio respectively.

Further, the H₂O partial pressure in a sputtering film forming atmosphere having a great influence on an orientation degree of the (001) plane direction of the KNN film, was measured by a quadrupol mass spectrometer before immediately before starting the film formation in a state of a total pressure of the atmosphere gas (1.3 Pa) which is the same pressure as the pressure during film formation. Here, the partial pressure obtained from a signal of a mass number 18 was regarded as the H₂O partial pressure. When a film formation substrate (Pt/Ti/SiO₂/Si substrate) is introduced to a sputtering device, a small quantity of moisture is introduced into a chamber together with the substrate. The partial pressure caused by such moisture, is gradually reduced with elapse of time by vacuum drawing while heating the substrate. By starting the sputtering film formation at a time point when the partial pressure of the moisture in the atmosphere becomes a desired value, an orientation state of the (001) plane direction of the KNN film was controlled, to thereby control the c/a ratio of the KNN film. Note that in a case of a different capacity of the sputtering chamber, a different electrode size, a different setting position of the quadrupol mass spectrometer, and a different sputtering film forming conditions (such as substrate temperature, substrate-target distance, discharge power, and Ar/O₂ ratio), they have a slight influence on the c/a ratio of the KNN film. Therefore, the relation between the c/a ratio and the H₂O partial pressure in the atmosphere gas is not uniquely determined. However, in many cases, the c/a ratio can be controlled by the H₂O partial pressure.

Then, the Pt upper electrode (having a film thickness of 100 nm) was formed on the KNN film which is formed as described above, by the RF magnetron sputtering method. The Pt upper electrode was formed under a condition of not heating the substrate, discharge power:200 W, introduced gas:Ar, pressure:2.5 Pa, and film formation time:1 minute.

Thus, the KNN film and the upper electrode were formed on the film formation substrate (Pt/Ti/SiO₂/Si substrate), to thereby fabricate the piezoelectric film element.

Table 1 and table 2 show measurement results of d₃₁ after one billion times drive/initial d₃₁×100(%) in examples 1 to 22 and comparative examples 1 to 14 of the piezoelectric film element thus formed. Table 1 and table 2 show a list of the composition of the KNN sintered compact target, the H₂O partial pressure (Pa), the c/a ratio of the KNN film, the composition of the KNN film, and d₃₁ after one billion times drive/initial d₃₁×100 (%).

Regarding the composition of the KNN sintered compact target, the atomic number % of K, Na, Nb was measured by the EDX((Energy Dispersive X-ray spectrometry), to thereby calculate the (K+Na)/Nb ratio and the Na/(K+Na) ratio respectively.

The H₂O partial pressure (Pa) when starting sputter film formation, was measured by the quadrupol mass spectrometer immediately before starting the film formation in a state of a total pressure of the atmosphere gas (1.3 Pa) which is the same pressure as the pressure during film formation. Here, the partial pressure obtained from a signal of a mass number 18 was regarded as the H₂O partial pressure.

The c/a ratio of the KNN film was obtained by the X-ray diffraction measurement (2θ/θ method) and the In-plane X-ray diffraction measurement performed to the KNN piezoelectric film. FIG. 6 and FIG. 8 show the results of example 4 in table 1. Then, it was found that all KNN piezoelectric films had a pseudo-cubic structure and were preferentially oriented in the (001) plane direction. The ratio of the out-of-plane lattice constant (c) to the in-plane lattice constant (a) of each KNN piezoelectric film was calculated from these X-ray diffraction patterns.

A composition analysis was performed to the composition of the KNN film by an ICP-AES(Inductively Coupled Plasma Atomic Emission Spectrometry method). Wet Acids Digestion was used in the analysis, and a mixed solution of hydrofluoric acid and nitric acid was used as acids. The (K+Na)/Nb ratio and the Na/(K+Na) ratio were calculated from the ratio of the analyzed Nb, Na, and K.

In both examples and comparative examples, the sputtering film formation time of each KNN film was adjusted so that a film thickness of the KNN film was approximately 3 μm.

d₃₁ after one billion times drive/initial d₃₁×100 (%) was obtained by measuring the piezoelectric constant d₃₁ when applying sin wave voltage of 600 Hz having an application field of 66.7 kV/cm(voltage of 20V applied to the KNN film with a thickness of 3 μm), using 104 GPa as the Young modulus of the Knn piezoelectric film of a piezoelectric sample. Further, the sin wave voltage of 600 Hz was continuously applied, to thereby measure d₃₁ again after one billion times drive of the cantilever (d₃₁ after one billion times drive).

Wherein, the piezoelectric sample was fabricated by forming the Pt upper electrode (having a film thickness of 100 nm) on the KNN piezoelectric film of examples 1 to 22 and comparative examples 1 to 14 by the RF magnetron sputtering method, which was then cut-out into rectangular beams having a length of 15 mm and a width of 2.5 mm.

TABLE 1

| | | | Film formation start | | | | d₃₁ after one billion |
|---|---|---|---|---|---|---|---|
| | KNN sintered compact target | | time | KNN film | | | times drive |
| | | (K + Na)/Nb | H₂O partial pressure | c/a | Na/(K + Na) ratio | (K + Na)/Nb ratio | Initial time d₃₁ × 100 |
| | Na/(K + Na) ratio | ratio | (Pa) | ratio | X | Y | (%) |
| Com. Ex. 1 | 0.57 | 0.97 | 1.2E−05 | 0.978 | 0.51 | 0.86 | 75 |
| Com. Ex. 2 | 0.46 | 0.93 | 1.2E−05 | 0.980 | 0.42 | 0.82 | 83 |
| Com. Ex. 3 | 0.75 | 0.90 | 1.1E−05 | 0.983 | 0.69 | 0.79 | 85 |
| Ex. 1 | 0.59 | 0.88 | 1.1E−05 | 0.985 | 0.55 | 0.77 | 101 |
| Ex. 2 | 0.43 | 1.05 | 1.0E−05 | 0.987 | 0.40 | 0.90 | 101 |
| Ex. 3 | 0.65 | 0.84 | 9.5E−06 | 0.990 | 0.59 | 0.78 | 100 |
| Ex. 4 | 0.61 | 0.99 | 9.0E−06 | 0.990 | 0.55 | 0.89 | 100 |
| Ex. 5 | 0.48 | 0.91 | 8.5E−06 | 0.991 | 0.44 | 0.80 | 97 |
| Ex. 6 | 0.71 | 0.99 | 8.0E−06 | 0.993 | 0.68 | 0.84 | 101 |
| Ex. 7 | 0.73 | 0.86 | 7.5E−06 | 0.996 | 0.69 | 0.79 | 98 |
| Ex. 8 | 0.60 | 0.91 | 7.0E−06 | 1.000 | 0.56 | 0.81 | 96 |
| Ex. 9 | 0.55 | 1.02 | 6.5E−06 | 1.002 | 0.51 | 0.88 | 98 |
| Ex. 10 | 0.76 | 0.94 | 6.0E−06 | 1.004 | 0.70 | 0.87 | 97 |
| Ex. 11 | 0.73 | 0.90 | 5.5E−06 | 1.005 | 0.66 | 0.82 | 100 |
| Ex. 12 | 0.68 | 0.94 | 5.0E−06 | 1.008 | 0.61 | 0.83 | 103 |
| Com. Ex. 4 | 0.66 | 0.92 | 4.5E−06 | 1.010 | 0.60 | 0.80 | 73 |
| Com. Ex. 5 | 0.60 | 1.04 | 4.0E−06 | 1.012 | 0.55 | 0.89 | 70 |
| Com. Ex. 6 | 0.56 | 0.93 | 3.5E−06 | 1.013 | 0.52 | 0.85 | 65 |

Com. Ex. = Comparative example
Ex. = Example

In table 1, the c/a ratio of the KNN film was increased by reducing the H₂O ratio when starting film formation, in a range of 0.40≦x≦0.70 and 0.77≦y≦0.90.

TABLE 2

| | | | Film formation start | | | | d₃₁ after one billion |
|---|---|---|---|---|---|---|---|
| | KNN sintered compact target | | time | KNN film | | | times drive |
| | | (K + Na)/Nb | H₂O partial pressure | c/a | Na/(K + Na) ratio | (K + Na)/Nb ratio | Initial time d₃₁ × 100 |
| | Na/(K + Na) ratio | ratio | (Pa) | ratio | X | Y | (%) |
| Com. Ex. 7 | 0.47 | 0.82 | 1.1E−05 | 0.987 | 0.42 | 0.73 | 66 |
| Com. Ex. 8 | 0.64 | 0.84 | 7.5E−06 | 0.995 | 0.58 | 0.74 | 69 |
| Com. Ex. 9 | 0.64 | 0.85 | 8.0E−06 | 0.993 | 0.59 | 0.75 | 79 |
| Com. Ex. 10 | 0.59 | 0.86 | 6.0E−06 | 1.003 | 0.55 | 0.75 | 83 |
| Ex. 13 | 0.74 | 0.90 | 7.0E−06 | 0.999 | 0.69 | 0.77 | 101 |
| Ex. 14 | 0.77 | 0.85 | 5.5E−06 | 1.005 | 0.70 | 0.79 | 100 |
| Ex. 15 | 0.50 | 0.89 | 1.1E−05 | 0.985 | 0.45 | 0.80 | 100 |
| Ex. 16 | 0.59 | 0.92 | 7.0E−06 | 1.007 | 0.55 | 0.81 | 97 |
| Ex. 17 | 0.53 | 0.98 | 9.5E−06 | 0.989 | 0.51 | 0.83 | 101 |
| Ex. 18 | 0.64 | 0.91 | 7.5E−06 | 0.997 | 0.60 | 0.83 | 98 |
| Ex. 19 | 0.63 | 0.94 | 7.0E−06 | 1.006 | 0.59 | 0.84 | 96 |
| Ex. 20 | 0.57 | 0.98 | 7.0E−06 | 1.000 | 0.53 | 0.85 | 98 |
| Ex. 21 | 0.56 | 0.96 | 9.5E−06 | 0.989 | 0.51 | 0.89 | 97 |
| Ex. 22 | 0.44 | 0.99 | 7.0E−06 | 1.002 | 0.40 | 0.90 | 100 |
| Com. Ex. 11 | 0.77 | 1.04 | 8.5E−06 | 0.991 | 0.69 | 0.92 | 87 |
| Com. Ex. 12 | 0.67 | 1.06 | 7.5E−06 | 0.997 | 0.61 | 0.93 | 85 |
| Com. Ex. 13 | 0.60 | 1.08 | 6.5E−06 | 1.008 | 0.55 | 0.93 | 83 |
| Com. Ex. 14 | 0.54 | 1.03 | 9.0E−06 | 0.990 | 0.50 | 0.94 | 80 |

Com. Ex. = Comparative example
Ex. = Example

In table 2, the (K+Na)/Nb ratio of the KNN film was increased by increasing (K+Na)/Nb ratio (y) of the KNN sintered compact target, in a range of 0.985≦c/a≦1.008 and 0.40≦y≦0.7.

Here, in order to facilitate the understanding, FIG. 10 shows a relation between d₃₁ after one billion times drive/initial d₃₁×100 (%), and the c/a ratio in table 1 (results of examples 1 to 12, and comparative examples 1 to 6). When the composition of the KNN film is in a range of 0.40≦x≦0.70 and 0.77≦y≦0.90, d₃₁ after one billion times drive/initial d₃₁×100 (%) is maintained to 95% or more in a case that the ratio of the out-of-plane lattice constant (c) to the in-plane lattice constant (a) of the KNN film is in a range of 0.985 c/a 1.008, and d31 after one billion times drive/initial d₃₁×100 (%) is 95% or less in a case that the c/a ratio is outside of the range of 0.985 c/a 1.008.

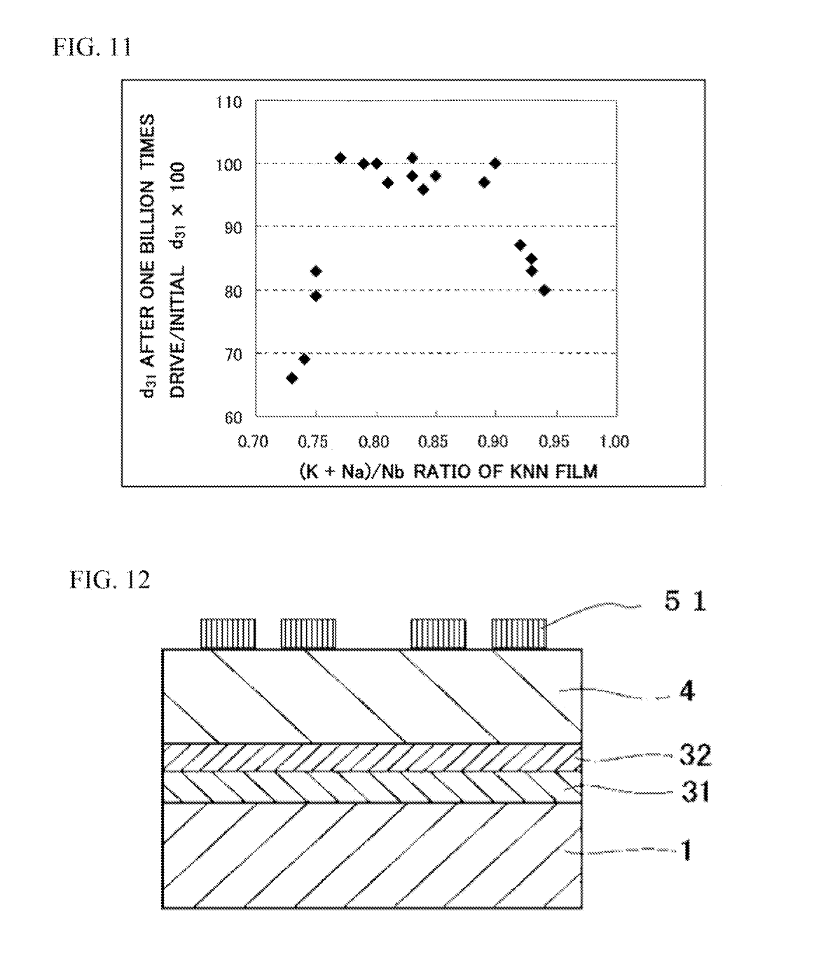

Next, similarly, FIG. 11 shows the relation between d₃₁ after one billion times drive/initial d₃₁×100 (%), in table 2, and the (K+Na)/Nb ratio (examples 13 to 22, comparative examples 7 to 14). When the ratio of the out-of-plane lattice constant (c) to the in-plane lattice constant (a) of the KNN film is in a range of 0.985≦c/a≦1.008, it is found that d₃₁ after one billion times drive/initial d₃₁×100 (%) is maintained to 95% or more in a case that the composition of the KNN film is in a range of 0.40≦x≦0.70 and 0.77≦y≦0.90, and when the (K+Na)/Nb ratio is outside of this range, d31 after one billion times drive/initial d₃₁×100 (%) is 95% or less.

From these results, it is found that when the composition of the KNN film is in a range of 0.40≦x≦0.70 and 0.77≦y≦0.90 and when the ratio of the out-of-plane lattice constant (c) to the in-plane lattice constant (a) of the KNN piezoelectric film is in a range of 0.985≦c/a≦1.008, the KNN piezoelectric film element with piezoelectric properties being 95% or more after one billion times drive, with an initial property as a reference, can be realized.

The present application is based on Japanese Patent Applications, No. 2010-155165 filed on Jul. 7, 2010, the entire contents of which are hereby incorporated by reference.

### DESCRIPTION OF SIGNS AND NUMERALS

1 Substrate
2 Lower electrode
3 Piezoelectric film
4 Upper electrode
5 Oxide film
6 Adhesive layer
10 Piezoelectric film element
11 Voltage detector or function generator

1. A piezoelectric film element, comprising:
a substrate; and
a piezoelectric film having an alkali niobium oxide-based perovskite structure represented by a composition formula (K₁₋ₓNaₓ)_{y}NbO₃ (0<x<1) provided on the substrate,
wherein the alkali niobium oxide-based composition falls within a range of 0.40≦x≦0.70 and 0.77≦y≦0.90, and further a ratio of an out-of-plane lattice constant (c) to an in-plane lattice constant (a) of the (K₁₋ₓNaₓ)_{y}NbO₃ film is set in a range of 0.985≦c/a≦1.008.

2. The piezoelectric film element according to claim 1, wherein when there are multiple layers of the piezoelectric film, a layer with a thickest thickness out of the multiple layers satisfies the range of the aforementioned composition and c/a ratio.

3. The piezoelectric film element according to claim 1, wherein the piezoelectric film has a pseudo-cubic structure and is preferentially oriented in (001) plane direction.

4. The piezoelectric film element according to claim 1, wherein a base layer is provided between the substrate and the piezoelectric film

5. The piezoelectric film element according to claim 4, wherein the base layer is a Pt film or an alloy film mainly composed of Pt, or an electrode layer with a lamination structure including a lower electrode mainly composed of Pt.

6. The piezoelectric film element according to claim 5, wherein an upper electrode can be formed on the piezoelectric film.

7. The piezoelectric film element according to claim 1, wherein the substrate is a Si substrate, a surface oxide film-attached Si substrate, or an SOI substrate.

8. A piezoelectric film device, comprising:
the piezoelectric film element according to claim 6; and
a function generator or a voltage detector connected between the lower electrode and the upper electrode.
